(19) United States
(12) Patent Application Publication
(10) Pub. No.: US 2006/0157865 A1
(43) Pub. Date: Jul. 20, 2006

(54) Circuit board and manufacturing method therefor and semiconductor package and manufacturing method therefor

(76) Inventor: Sumio Hokari, Kanagawa (JP)

Correspondence Address: David R. Metzger;SONNENSCHEIN NATH & ROSENTHAL, Sears Tower, Wacker Drive Station, P.O. Box 061080, Chicago, IL, 60606-1080, US

(21) Appl. No.: 11/329,667

(22) Filed: Jan. 11, 2006

(30) Foreign Application Priority Data
Jan. 20, 2005 (JP) P2005-013244

(51) Int. Cl. H01L 23/48; H01L 23/52; H01L 29/40

(52) U.S. Cl. 257/774

(57) ABSTRACT

A circuit board includes a circuit board body having a semiconductor device mounting area for mounting a semiconductor device, a wiring pattern to be electrically connected to a semiconductor device to be mounted on the semiconductor device mounting area, and an insulating layer for covering the wiring pattern, the insulating layer having openings formed therein at regions on which bumps for electrically connecting the wiring pattern to a mount substrate are disposed. The opening sizes of the openings are allowed to vary depending on the positions at which the openings are formed.

### CROSS REFERENCES TO RELATED APPLICATIONS

The present invention contains subject matter related to Japanese Patent Application JP 2005-013244 filed in the Japanese Patent Office on Jan. 20, 2005, the entire contents of which are incorporated herein by reference.

### BACKGROUND OF THE INVENTION

1. Field of the Invention

The present invention relates to a circuit board and a manufacturing method therefor and a semiconductor package and a manufacturing method therefor. More particularly, the invention relates to a circuit board in which good terminal flatness is achieved, thus improving the mounting yield, a method for manufacturing the circuit board, a semiconductor package including such a circuit board, and a method for manufacturing the semiconductor package.

2. Description of the Related Art

With the reduction in size and weight, increase in operational speed, and increase in functionality of electronic equipment, miniaturization and integration of semiconductor devices have been demanded. It has become physically difficult to meet such demands simply by increasing the number of pins of semiconductor chips. Recently, instead of pin-insertion-type semiconductor packages, ball grid array (BGA) semiconductor packages and land grid array (LGA) semiconductor packages have been proposed. For example, refer to Japanese Unexamined Patent Application Publication No. 11-102988.

A known BGA semiconductor package will be described below with reference to the drawings.

FIGS. 5A and 5B are a schematic sectional view and a schematic bottom view, respectively, of a known semiconductor package. A semiconductor package 101 includes an interposer substrate 102, a semiconductor chip 103 die-bonded to the upper surface of the interposer substrate 102, and a sealing resin 104 which seals the semiconductor chip 103.

Each chip electrode of the semiconductor chip 103 is wire-bonded via a thin gold wire 106 to an outgoing line of a chip mount surface wiring pattern 105 formed on a chip mount surface of the interposer substrate 102. The chip mount surface wiring pattern 105 is connected through the interposer substrate 102 to a substrate mount surface wiring pattern 107 formed on a substrate mount surface (a surface facing a mount substrate). Outgoing lines of the substrate mount surface wiring pattern 107 are connected to external terminals (lands) disposed on the substrate mount surface. A nickel plating layer 108 is formed on each land and the end of the outgoing line of the wiring pattern 107 connected to the land, and a gold plating layer 109 is formed on the nickel plating layer 108.

Furthermore, the outgoing lines are covered with a solder resist layer 111 provided with openings 110 in the land forming regions. Each land is electrically connected to a solder ball 112 (see FIG. 6) through the opening. Note that the opening size (indicated by symbol A in FIG. 5A) of the opening formed in the solder resist layer 111 is the same for all lands.

As shown in FIG. 6, the semiconductor package 101 having the structure described above is mounted on a mount substrate 113 by bonding the solder balls 112 to terminals 114 of the mount substrate 113.

A method for manufacturing the semiconductor package having the structure described above will be described below.

In the manufacturing method of the known semiconductor package, first, as shown in FIG. 7A, a die pad 115 for mounting a semiconductor chip and a chip mount surface wiring pattern 105 are formed on a chip mount surface of an interposer substrate 102, and a substrate mount surface wiring pattern 107 and lands are formed on a substrate mount surface which is opposite to the chip mount surface.

Subsequently, as shown in FIG. 7B, after a photoresist 116 is applied to the entire surfaces of the interposer substrate 102, the photoresist placed on the die pad 115 and the bases of the outgoing lines of the chip mount surface wiring pattern 105 to be wire-bonded to chip electrodes of a semiconductor chip and on the lands and the ends of the outgoing lines of the substrate mount surface wiring pattern 107 is removed to expose these areas.

Subsequently, as shown in FIG. 7C, by performing nickel plating, nickel plating layers 108 are formed on the exposed die pad 115, bases of the outgoing lines of the chip mount surface wiring pattern 105, lands, and ends of the outgoing lines of the substrate mount surface wiring pattern 107. Then, by performing gold plating, gold plating layers 109 are formed on the nickel plating layers 108 formed on the exposed die pad 115, bases of the outgoing lines of the chip mount surface wiring pattern 105, lands, and ends of the outgoing lines of the substrate mount surface wiring pattern 107.

Subsequently, the photoresist is removed, and then, as shown in FIG. 7D, a solder resist is applied to the entire surfaces of the interposer substrate 102 to form solder resist layers 111. Subsequently, as shown in FIG. 7E, the solder resist placed on the die pad 115, the bases of the outgoing lines of the chip mount surface wiring pattern 105, and the lands is removed to form openings 110 to expose the gold plating layers 109 on the lands. The solder resist is removed such that the opening sizes of the openings formed on the lands are the same for all lands.

Subsequently, a semiconductor chip 103 is fixed on the die pad 115 with a mounting material 117 therebetween, and each chip electrode of the semiconductor chip 103 is bonded to an outgoing line of the chip mount surface wiring pattern 105 via a thin gold wire 106. Then, the semiconductor chip 103, the thin gold wires 106, the chip mount surface wiring pattern 105, etc., are sealed with a sealing resin 104, and a semiconductor package 101 shown in FIG. 7F is thereby obtained.

### SUMMARY OF THE INVENTION

With respect to the known semiconductor package, which has been described above, when the semiconductor package is mounted on a mount substrate by bonding the terminals of the mount substrate to solder balls, warpage occurs in the semiconductor package in a temperature atmosphere near the melting point of the solder balls, resulting in degradation in mounting reliability.

That is, when the semiconductor package is warped concavely, the solder balls in the peripheral regions of the semiconductor package are not in contact with the terminals of the mount substrate, and connection is not achieved even if the solder melts. Similarly, when the semiconductor package is warped convexly, the solder balls in the central region of the semiconductor package are not in contact with the terminals of the mount substrate, and connection is not achieved even if the solder melts. For this reason, with respect to the known semiconductor package, the mounting reliability is low.

It is desirable to provide a circuit board capable of producing a semiconductor package having high mounting reliability with respect to a mount substrate, a method for manufacturing the circuit board, a semiconductor package including such a circuit board, and a method for manufacturing the semiconductor package.

According to an embodiment of the present invention, a circuit board includes a circuit board body having a semiconductor device mounting area for mounting a semiconductor device, a wiring pattern to be electrically connected to a semiconductor device to be mounted on the semiconductor device mounting area, and an insulating layer for covering the wiring pattern, the insulating layer having openings formed therein at regions on which bumps for electrically connecting the wiring pattern to a mount substrate are disposed, wherein the opening sizes of the openings are allowed to vary depending on the positions at which the openings are formed.

According to another embodiment of the present invention, a method for manufacturing a circuit board includes the steps of forming a wiring pattern on a circuit board body, the wiring pattern to be electrically connected to a semiconductor device to be mounted on the circuit board body, covering the wiring pattern with an insulating layer, and forming openings in the insulating layer at regions on which bumps for electrically connecting the wiring pattern to a mount substrate are disposed, wherein the opening sizes of the openings are allowed to vary depending on the positions at which the openings are formed.

According to another embodiment of the present invention, a semiconductor package includes a semiconductor device, a wiring pattern electrically connected to the semiconductor device, an insulating layer which covers the wiring pattern, and a sealing resin which seals the semiconductor device, the insulating layer having openings formed therein at regions on which bumps for electrically connecting the wiring pattern to a mount substrate are disposed, wherein the opening sizes of the openings are allowed to vary depending on the positions at which the openings are formed.

According to another embodiment of the present invention, a method for manufacturing a semiconductor package includes the steps of forming a wiring pattern on a circuit board body, the wiring pattern to be electrically connected to a semiconductor device to be mounted on the circuit board body, covering the wiring pattern with an insulating layer, forming openings in the insulating layer at regions on which bumps for electrically connecting the wiring pattern to a mount substrate are disposed, and mounting a semiconductor device on the circuit board body, electrically connecting the wiring pattern to the semiconductor device, and then sealing the semiconductor device with a resin, wherein the opening sizes of the openings are allowed to vary depending on the positions at which the openings are formed.

Here, by allowing the opening sizes of the openings to vary depending on the positions at which the openings are formed, it is possible to vary the heights of the bumps depending on the positions at which the openings are formed.

That is, when bumps are formed, generally, the same amount of a bump material is supplied to the opening areas of the insulating layer on which bumps are formed (e.g., solder balls with the same diameter and the same mass are placed at all the openings), and then the bump material is melted by applying heat to form bumps. In the case where the same amount of bump material is supplied to the opening areas and then heating is performed, when the opening size of the opening is large, the height of the resulting bump after heating is low (refer to FIG. 9A), and when the opening size of the opening is small, the height of the resulting bump after heating is high (refer to FIG. 9B).

Consequently, by decreasing the opening size of the openings in regions in which the distance between a circuit board and a mount substrate on which the circuit board is mounted is large (e.g., peripheral regions indicated by symbol B in FIG. 8A in which a semiconductor package is warped concavely, and a central region indicated by symbol C in FIG. 8B in which a semiconductor package is warped convexly) and by increasing the opening size of the openings in regions in which the distance between a circuit board and a mount substrate is small (e.g., a central region in FIG. 8A and peripheral regions in FIG. 8B), it is possible to form high bumps in the regions in which the distance between the circuit board and the mount substrate is large and to form low bumps in the regions in which the distance between the circuit board and the mount substrate is small.

When all openings in an insulating layer are formed with the same opening size, as described in Japanese Unexamined Patent Application Publication No. 10-107176, it is conceivable to allow the height of bumps to vary by supplying different amounts of a bump material depending on the positions at which openings are formed, for example, increasing the amount of the bump material supplied when high bumps are formed, and decreasing the amount of the bump material supplied when low bumps are formed. However, in order to supply different amounts of a bump material depending the positions at which openings are formed, the number of process steps for supplying the bump material may be increased, resulting in a decrease in yield, controlling of the height of bumps may become insufficient, or a highly accurate bump material feeder (e.g., a solder ball mounting apparatus) may be needed. Thus, such a method is not necessarily appropriate.

In the circuit board according to the embodiment of the present invention or a semiconductor package including a circuit board manufactured by the method for manufacturing the circuit board according to the embodiment of the present invention, the semiconductor package according to the embodiment of the prevent invention or a semiconductor package manufactured by the method for manufacturing the semiconductor package according the embodiment of the present invention, even if warpage occurs when the semiconductor package is mounted in a mount substrate, mounting reliability with respect to a mount substrate can be improved.

### BRIEF DESCRIPTION OF THE DRAWINGS

FIGS. 1A and 1B are a schematic sectional view and a schematic bottom view, respectively, of a semiconductor package according to an embodiment of the present invention;

FIGS. 2A to 2D are schematic sectional views illustrating a method for manufacturing a semiconductor package according to an embodiment of the present invention;

FIG. 3 is a schematic sectional view illustrating solder balls formed in the semiconductor package according to the embodiment of the present invention;

FIGS. 4A and 4B are sectional views, each illustrating mounting of a semiconductor package according to an embodiment of the present invention on a mount substrate;

FIGS. 5A and 5B are a schematic sectional view and a schematic bottom view, respectively, of a known semiconductor package;

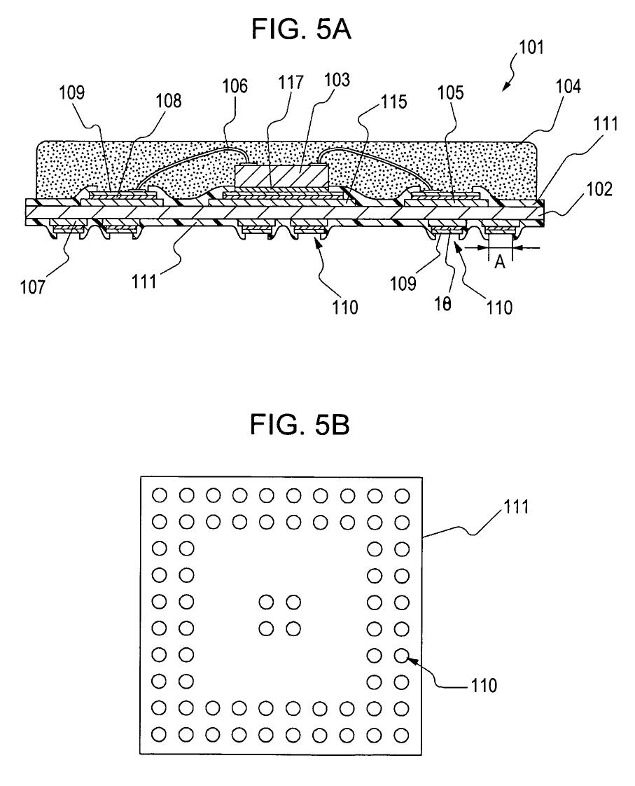

FIG. 6 is a schematic sectional view illustrating mounting of the known semiconductor package on a mount substrate;

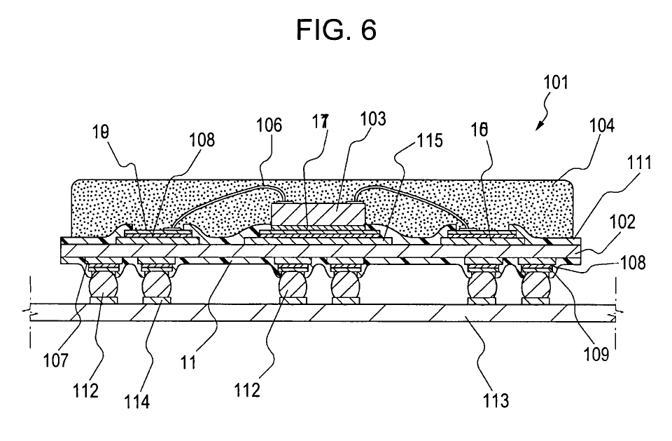

FIGS. 7A to 7F are sectional views illustrating a method for manufacturing a known semiconductor package;

FIGS. 8A and 8B are schematic sectional views illustrating warpage of semiconductor packages; and

FIGS. 9A and 9B are sectional views, each illustrating the relationship between an opening and the height of a bump.

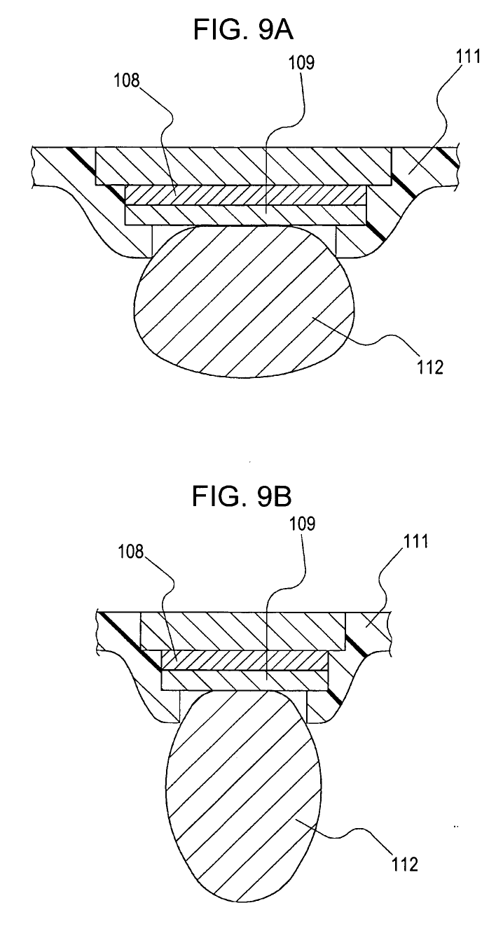

### DESCRIPTION OF THE PREFERRED EMBODIMENTS

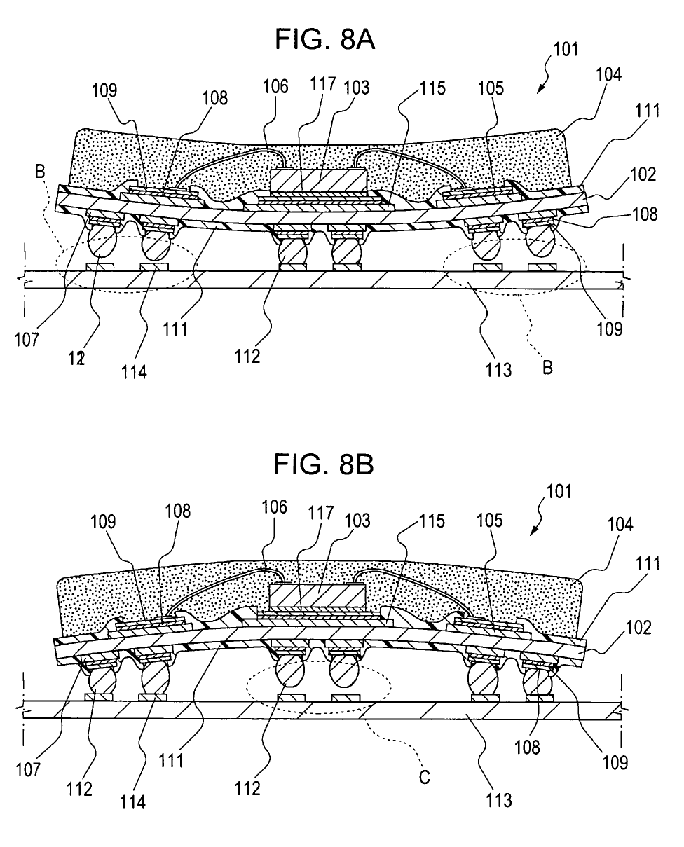

Embodiments of the present invention will be described with reference to the drawings. In the embodiments below, a semiconductor package in which concave warpage occurs when the semiconductor package is mounted on a mount substrate will be described as an example (refer to FIG. 8A).

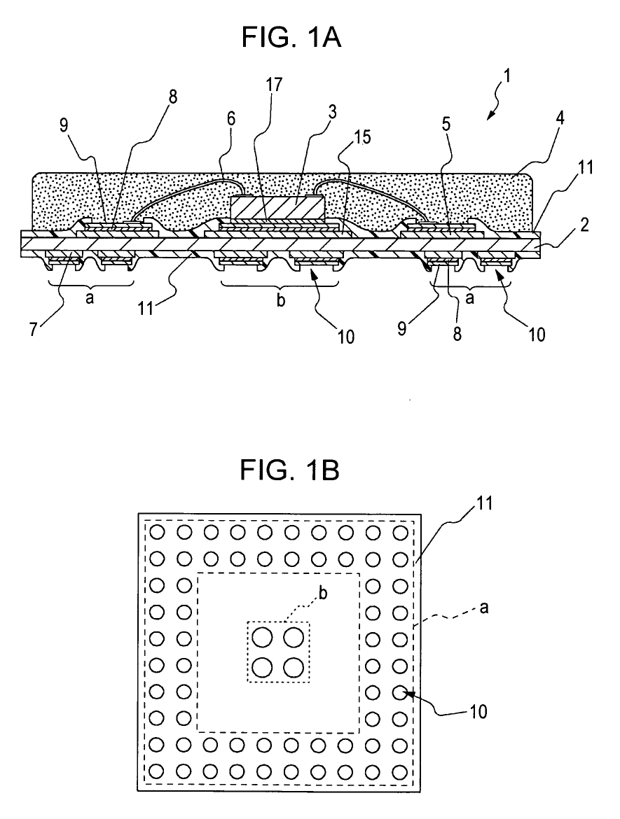

FIGS. 1A and 1B are a schematic sectional view and a schematic bottom view, respectively, of a semiconductor package according to an embodiment of the present invention. A semiconductor package 1 includes an interposer substrate 2, a semiconductor chip 3 die-bonded to the upper surface of the interposer substrate 2, and a sealing resin 4 which seals the semiconductor chip 3, similar to the semiconductor package 101 described above.

Each chip electrode of the semiconductor chip 3 is wire-bonded via a thin gold wire 6 to an outgoing line of a chip mount surface wiring pattern 5 formed on a chip mount surface of the interposer substrate 2. The chip mount surface wiring pattern 5 is connected through the interposer substrate 2 to a substrate mount surface wiring pattern 7 formed on a substrate mount surface. Outgoing lines of the substrate mount surface wiring pattern 7 are connected to lands disposed on the substrate mount surface. A nickel plating layer 8 is formed on each land and the end of the outgoing line of the wiring pattern 7 connected to the land, and a gold plating layer 9 is formed on the nickel plating layer 8.

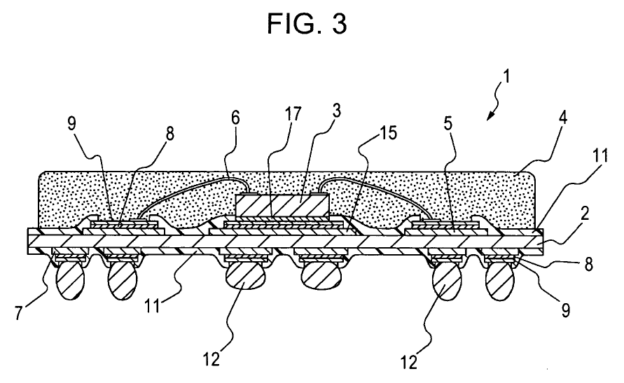

Furthermore, the outgoing lines are covered with a solder resist layer 11 provided with openings 10 in the land forming regions. Each land is electrically connected to a solder ball 12 (see FIG. 3) through the opening.

In the semiconductor package according to the embodiment of the present invention, the opening size of the openings 10 formed in the solder resist layer 11 in the central region (indicated by symbol b in FIGS. 1A and 1B) of the semiconductor package 1 is larger than the opening size of the openings 10 formed in the solder resist layer 11 in the peripheral regions (indicated by symbol a in FIGS. 1A and 1B).

The reason for that the opening size of the openings 10 formed in the solder resist layer 11 in the central region of the semiconductor package 1 is set to be larger than the opening size of the openings 10 formed in the solder resist layer 11 in the peripheral regions is that the semiconductor package 1 according to the embodiment of the present invention warps concavely during mounting on a mount substrate. That is, the semiconductor package 1 changes its shape such that the distance between the peripheral region of the semiconductor package 1 and the mount substrate is larger than the distance between the central region of the semiconductor package 1 and the mount substrate.

Consequently, when the semiconductor package 1 changes its shape such that the distance between the central region of the semiconductor package 1 and the mount substrate is larger than the distance between the peripheral region of the semiconductor package 1 and the mount substrate during mounting on the mount substrate (for example, as shown in FIG. 8B, when the semiconductor package warps convexly), it is necessary to set the size of the openings formed in the solder resist in the central region to be smaller than the size of the openings formed in the solder resist in the peripheral region.

A method for manufacturing the semiconductor package described above will be described below. That is, a method for manufacturing a semiconductor package according to an embodiment of the present invention will be described below.

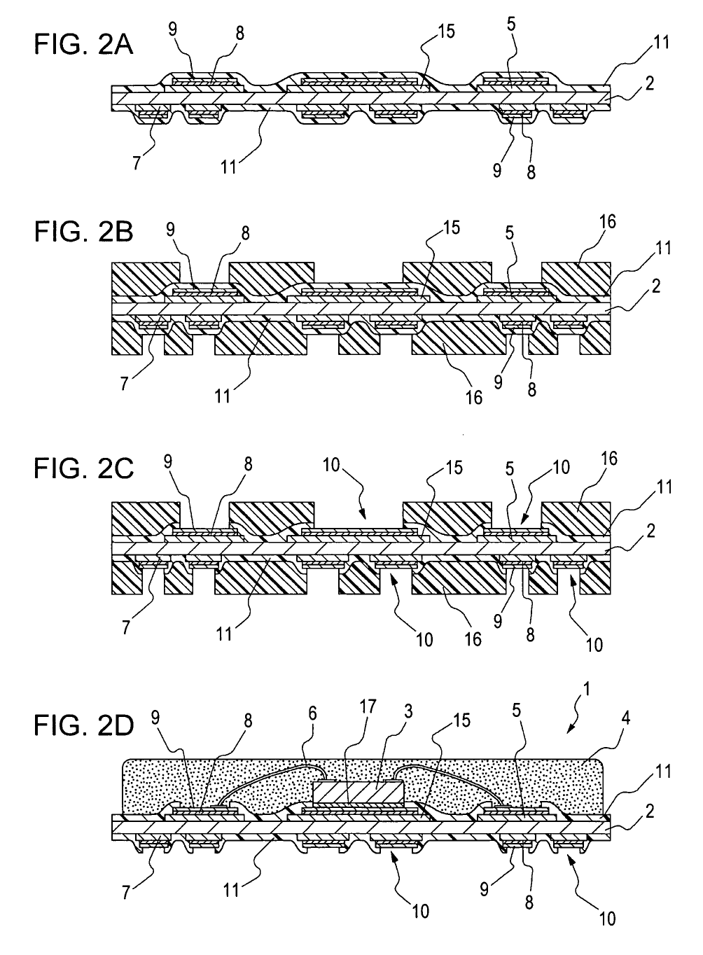

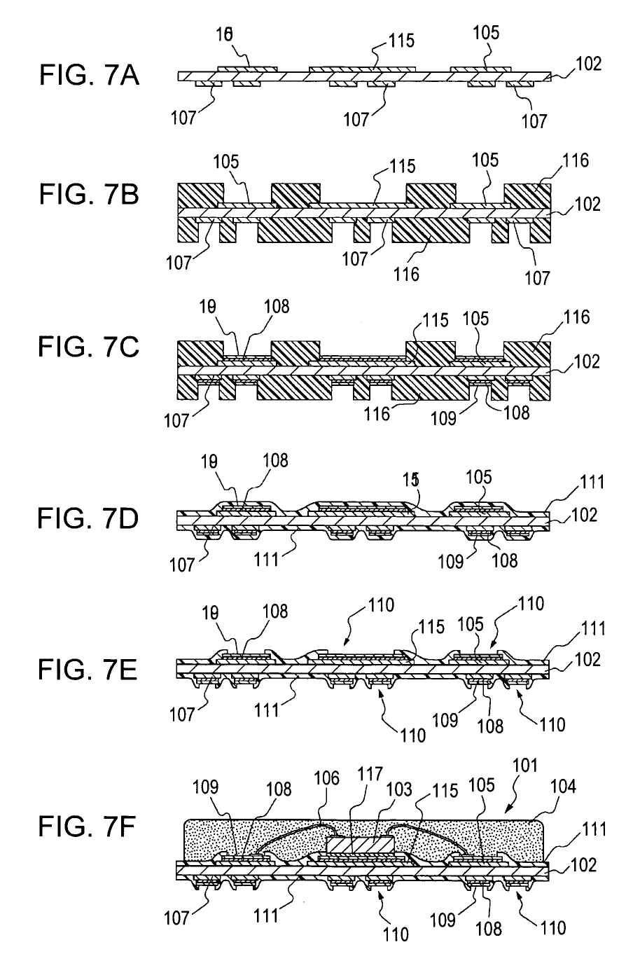

In the method for manufacturing the semiconductor package according to the embodiment of the present invention, in a manner similar to that in the method for manufacturing the known semiconductor package 101 (refer to FIGS. 7A to 7D), a die pad 15, a chip mount surface wiring pattern 5, a substrate mount surface wiring pattern 7, and lands are formed on an interposer substrate 2, and nickel plating layers 8 and gold plating layers 9 are formed. Subsequently, solder resist layers 11 are formed over the entire surfaces of the interposer substrate 2 (refer to FIG. 2A).

Subsequently, as shown in FIG. 2B, after a photoresist 16 is applied to the entire surfaces of the solder resist layers 11, the photoresist placed on the die pad 15 and the bases of the outgoing lines of the chip mount surface wiring pattern 5 to be wire-bonded to chip electrodes of a semiconductor chip and on the lands and the ends of the outgoing lines of the substrate mount surface wiring pattern 7 is removed to expose the solder resist.

The photoresist is then removed such that each opening area on the substrate mount surface of the photoresist in the central region of the semiconductor package is larger than each opening area on the substrate mount surface of the photoresist in the peripheral region of the semiconductor package, i.e., the area in which the photoresist is removed on the land and the end of the outgoing line of the substrate mount surface wiring pattern 7. Thereby, the area of the exposed solder resist on the substrate mount surface in the central region of the semiconductor package is larger than the area of the exposed solder resist on the substrate mount surface in the peripheral region of the semiconductor package.

Subsequently, as shown in FIG. 2C, by removing the exposed solder resist, openings 10 are formed on the die pad 15, the bases of the outgoing lines of the chip mount surface wiring pattern 5 to be wired-bonded to chip electrodes of a semiconductor chip and on the lands and the ends of the outgoing lines of the substrate mount surface wiring pattern 7 to expose the gold plating layers 9 on the lands. Note that, since the area of the exposed solder resist on the substrate mount surface in the central region of the semiconductor package is larger than the area of the exposed solder resist on the substrate mount surface in the peripheral region of the semiconductor package, the size of the openings formed in the solder resist on the substrate mount surface in the central region of the semiconductor package is larger than the size of the openings formed in the solder resist eon the substrate mount surface in the peripheral region of the semiconductor package.

Subsequently, a semiconductor chip 3 is fixed on the die pad 15 with a mounting material 17 therebetween, and each chip electrode of the semiconductor chip 3 is bonded to an outgoing line of the chip mount surface wiring pattern 5 via a thin gold wire 6. Then, the semiconductor chip 3, the thin gold wires 6, the chip mount surface wiring pattern 5, etc., are sealed with a sealing resin 4, and a semiconductor package 1 shown in FIG. 2D is thereby obtained.

In the semiconductor package according to the embodiment of the present invention described above, by supplying the same amount of a solder material to the openings of the solder resist, followed by reflow treatment, it is possible to obtain the heights of the solder balls 12 according to the opening sizes of the openings. That is, the height of the solder balls 12 in the peripheral regions of the semiconductor package 1 can be set higher than the height of the solder balls 12 in the central region of the semiconductor package 1 (refer to FIG. 3).

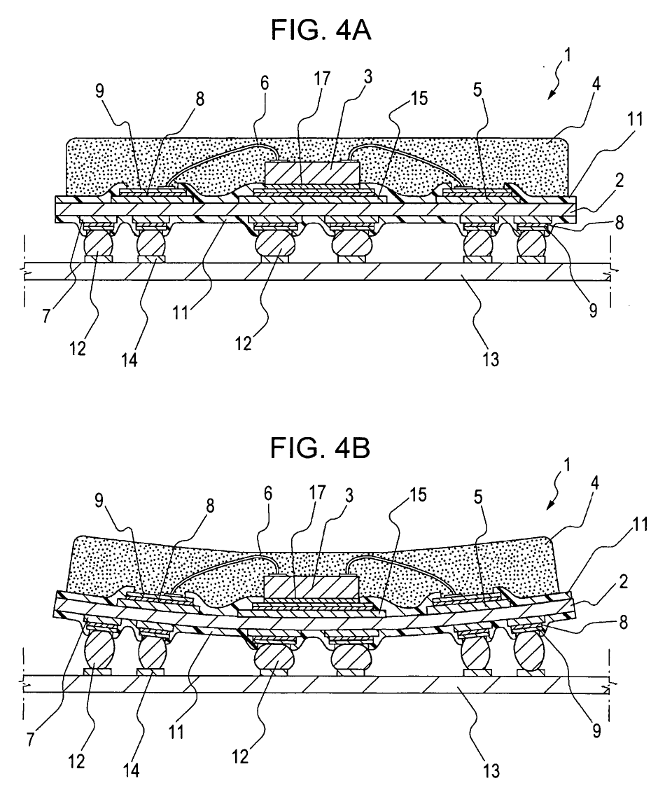

Consequently, as shown in FIG. 4A, when the semiconductor package 1 is attempted to be mounted on a mount substrate 13 by bonding the solder balls 12 to the terminals 14 of the mount substrate 13, even if warpage occurs in the semiconductor package 1 at temperatures near the melting point of the solder as shown in FIG. 4B, the difference in height of the solder balls 12 can reduce the deformation due to the warpage of the semiconductor package 1, and thus satisfactory mounting of the semiconductor package 1 can be achieved.

Furthermore, by setting the sizes of the openings in the solder resist to be different between the central region and the peripheral region of the semiconductor package, the height of the solder balls can be controlled. Thereby, it is possible to relatively easily control the height of the solder balls with high accuracy.

Control of the height of solder balls can be achieved by other methods, for example, (1) a method in which different amounts of a solder material are supplied by a squeegee to the peripheral region and the central region of a semiconductor package, and (2) a method in which fine solder balls with different volumes are mounted on openings of a solder resist layer. However, in method (1), it is difficult to control the height of solder balls with high accuracy; and in method (2), although the height of solder balls can be controlled with high accuracy, in order to mount fine solder balls with different volumes on openings of the solder resist layer, a highly accurate solder ball mounting apparatus may be required. In contrast, in the semiconductor package according to any of the embodiments of the present invention, it is not necessary to use a highly accurate solder ball mounting apparatus, the height of the solder balls can be controlled only by allowing the opening sizes of the openings in the solder resist layer to vary, and thus the height of solder balls can be relatively easily controlled with high accuracy.

It should be understood by those skilled in the art that various modifications, combinations, sub-combinations and alterations may occur depending on design requirements and other factors insofar as they are within the scope of the appended claims or the equivalents thereof.

What is claimed is:

1. A circuit board comprising:
a circuit board body having a semiconductor device mounting area for mounting a semiconductor device;
a wiring pattern to be electrically connected to a semiconductor device to be mounted on the semiconductor device mounting area; and
an insulating layer for covering the wiring pattern, the insulating layer having openings formed therein at regions on which bumps for electrically connecting the wiring pattern to a mount substrate are disposed,
wherein the opening sizes of the openings are allowed to vary depending on the positions at which the openings are formed.

2. The circuit board according to claim 1, wherein the opening sizes of the openings decrease as the distance between the circuit board and the mount substrate on which the circuit board is mounted increases.

3. A method for manufacturing a circuit board comprising the steps of:
forming a wiring pattern on a circuit board body, the wiring pattern to be electrically connected to a semiconductor device to be mounted on the circuit board body;
covering the wiring pattern with an insulating layer; and
forming openings in the insulating layer at regions on which bumps for electrically connecting the wiring pattern to a mount substrate are disposed,
wherein the opening sizes of the openings are allowed to vary depending on the positions at which the openings are formed.

4. The method for manufacturing the circuit board according to claim 3, wherein the opening sizes of the openings are decreased as the distance between the circuit board and the mount substrate on which the circuit board is mounted increases.

5. A semiconductor package comprising:
a semiconductor device;
a wiring pattern electrically connected to the semiconductor device;
an insulating layer which covers the wiring pattern, the insulating layer having openings formed therein at regions on which bumps for electrically connecting the wiring pattern to a mount substrate are disposed; and
a sealing resin which seals the semiconductor device,
wherein the opening sizes of the openings are allowed to vary depending on the positions at which the openings are formed.

6. The semiconductor package according to claim 5, wherein the opening sizes of the openings decrease as the distance between the semiconductor package and the mount substrate on which the semiconductor package is mounted increases.

7. A method for manufacturing a semiconductor package comprising the steps of:
forming a wiring pattern on a circuit board body, the wiring pattern to be electrically connected to a semiconductor device to be mounted on the circuit board body;
covering the wiring pattern with an insulating layer;
forming openings in the insulating layer at regions on which bumps for electrically connecting the wiring pattern to a mount substrate are disposed; and
mounting a semiconductor device on the circuit board body, electrically connecting the wiring pattern to the semiconductor device, and then sealing the semiconductor device with a resin,
wherein the opening sizes of the openings are allowed to vary depending on the positions at which the openings are formed.

8. The method for manufacturing the semiconductor package according to claim 7, wherein the opening sizes of the openings are decreased as the distance between the semiconductor package and the mount substrate on which the semiconductor package is mounted increases.
